(19) United States
(12) Patent Application Publication
(10) Pub. No.: US 2026/0063702 A1
(43) Pub. Date: Mar. 5, 2026

(54) Electronic Subassembly

(71) Applicant: Siemens Aktiengesellschaft, München (DE)

(72) Inventors: Stefan Nerreter, Heidesee OT Blossin (DE); Jörg Strogies, Berlin (DE); Ulrich Wetzel, Adelsdorf (DE)

(73) Assignee: Siemens Aktiengesellschaft, München (DE)

(21) Appl. No.: 19/309,275

(22) Filed: Aug. 25, 2025

(30) Foreign Application Priority Data
Aug. 30, 2024 (EP) 24197619.0

(51) Int. Cl. G01R 31/265; G01R 31/26

(52) U.S. Cl. CPC G01R 31/2656; G01R 31/2632

(57) ABSTRACT

Various embodiments of the teachings herein include an electronic subassembly. An example includes: an electronic component; a board; wherein the component and the board extend horizontally relative to each other in various layers within the subassembly; contacting means of the electronic component extending vertically in the subassembly; a glass sheet incorporated into the subassembly in a horizontal installation position; a horizontal opening in the glass sheet through which is routed at least part of the contacting means; an optical waveguide structured in the glass sheet; and two optical connection points for the waveguide by which polarized laser light can be coupled into and out of the waveguide. The glass sheet is arranged between a mounting plate and the component.

### CROSS-REFERENCE TO RELATED APPLICATIONS

This application claims priority to EP Application No. 24197619.0 filed Aug. 30, 2024, the contents of which are hereby incorporated by reference in their entirety.

### TECHNICAL FIELD

The present disclosure relates to electronics. Various embodiments of the teachings herein include electronic subassemblies.

### BACKGROUND

In electronic subassemblies, particularly in the field of power electronics, subassemblies which are installed in a power electronics module, chip-oriented measurement of the current that flows is desirable for the purpose of selectively controlling the subassemblies or modules. Currents are conventionally measured by means of so-called shunt resistors or so-called Hall converters which are located externally to the subassembly or module, for example. The possibility of measuring currents at individual components in a module or in a subassembly is not known.

### SUMMARY

The teachings of the present disclosure provide electronic subassemblies and power electronics modules which allow the measurement of currents flowing in the subassembly in the immediate vicinity of the chip, i.e. the component. For example, some embodiments include an electronic subassembly (2) having at least one electronic component (4) and at least one board (8), wherein component (4) and board (8) extend horizontally relative to each other in various layers (E1, E2 . . . En) within the subassembly (2), wherein contacting means (10) of the electronic component (4) extend vertically in the subassembly (2), characterized in that a glass sheet (12) is incorporated into the subassembly (2) in a horizontal installation position, said glass sheet (12) has a horizontal opening (14) through which is routed at least part of the contacting means (10), wherein an optical waveguide (16) is structured in the glass sheet (12), and the glass sheet has two optical connection points (32, 34) for the waveguide (15), by means of which polarized laser light (20) can be coupled into and out of the waveguide (16), and the glass sheet (12) with the opening (14) is arranged between a mounting plate (6) and the component (4).

In some embodiments, the component (4) is a power electronics component (4) and the subassembly (2) is a power electronics subassembly (2).

In some embodiments, the component (2) is a transistor (22) or diode.

In some embodiments, the component has at least two current-carrying contacting means (24, 26).

In some embodiments, at least one of the current-carrying contacting means (24, 26) extends through the opening (14) of the glass sheet (12).

In some embodiments, the contacting means (24, 26, 28) are embodied at least partly in the form of pins (40) and are routed vertically through the board (8, 8′).

In some embodiments, there is a laser diode (18), this being used to couple polarized laser light into the waveguide (16).

In some embodiments, there is a polarizer (42) and a photodiode (44), these being used to measure the intensity of laser light (2040 ) that is coupled out of the waveguide (16).

In some embodiments, the waveguide (16) extends within the glass sheet (12) at least once around the opening (14).

In some embodiments, the waveguide (16) is vertically redirected within the glass sheet (12) and extends in a plurality of layers of the glass sheet (12).

In some embodiments, there is an external waveguide (46) leading from the connection points (32, 34) is provided.

In some embodiments, the external waveguide (46) partially extends within a pin (50) which is provided for this purpose.

In some embodiments, the external waveguide (46) in the form of a glass body (52) is integrated into the pin (50).

In some embodiments, the external waveguide (46) extends at least partially in or on the board (8, 8′).

In some embodiments, the pin (50) extends through the board (8, 8′) through which, in which, or on which the waveguide (46) extends.

### BRIEF DESCRIPTION OF THE DRAWINGS

Further embodiment variants and further features of the teachings herein are explained in greater detail with reference to the following figures. These are purely schematic embodiment variants which do not in any way limit the extent of the disclosure. Features having the same designation and different embodiment variants in the individual figures are denoted by the same reference signs in this case. In the figures:

FIG. 1 shows a cross section through an electronic subassembly in the form of a power electronics subassembly with a thin glass sheet in which is structured a waveguide incorporating teachings of the present disclosure;

FIG. 2a shows a plan view of a glass sheet, a thin glass sheet having an opening and a waveguide which is structured therein;

FIG. 2b shows the glass sheet as per FIG. 2a in cross section;

FIG. 3 shows a schematic illustration of the electrical Faraday effect which is used for the measurement of the currents in electronic subassemblies;

FIG. 4 shows a similar subassembly to FIG. 1, having an alternative feed line of an external waveguide by means of a pin; and

FIG. 5 shows a magnified illustration of a possible pin according to FIG. 4.

### DETAILED DESCRIPTION

As an example, some embodiments of the teachings herein include an electronic subassembly with at least an electronic component and a board, component and board extending horizontally relative to each other in various planes within the subassembly. there are contacting means of the electronic component, these extending vertically in the subassembly. A glass sheet is incorporated in the subassembly in a horizontal installation position, said glass sheet having a horizontal opening through which at least part of the contacting means is routed. An optical waveguide is also structured in the glass sheet, said glass sheet having optical connection points for the optical waveguide, by means of which polarized laser light can be coupled into and out of the waveguide, said glass sheet with the opening being arranged in this case between a mounting plate for the component and the component itself. In some embodiments, a contacting layer is incorporated between the mounting plate, which again occupies a layer in the subassembly, and the component, and this contacting layer can be vertically extended so far that the opening of the glass sheet is filled by the contacting means.

The contacting means which pass vertically through the opening in the glass sheet induce a magnetic field around the contacting means when current flows through the contacting means, i.e. when current flows through the component itself, whereby as a result of the optical Faraday effect, polarized laser light which passes through the waveguide that is integrated into the glass sheet is deflected in its polarization. From the measurement of the change in the polarization of the laser light, for example using an optical detector, it is possible to infer the intensity of the electrical contacting means passing through the opening of the glass sheet in the subassembly. Since the glass sheet can be designed to be very small and is also very thin, usually having a thickness between 200 μm and 1 mm, it can be integrated without great technical cost into a layer of the subassembly in such a way that it can be arranged directly between the (usually ceramic) mounting plate and the component, and the structural space of the subassembly is increased only slightly.

This means that a chip-oriented, or part-oriented, measurement of current flows is possible for individual components, for example transistors and/or diodes within the subassembly, in particular within a power electronics subassembly in which power electronics components such as power transistors or diodes are installed. The subassembly can then be an element within a larger electronic system, for example a power electronics system such as an inverter, for example.

In some embodiments, the subassembly is designed such that the component has at least two current-carrying contacting means. There are usually two current-carrying contacting means in the case of a diode, and at least three current-carrying contacting means are present in the case of a transistor. It is appropriate in this case for at least one of the current-carrying contacting means to pass through the opening of the glass sheet. In the case of a transistor, in particular a field effect transistor, this can appropriately be the so-called drain contacting means, since higher voltages are present here.

In some embodiments, the contacting means are embodied at least partly in the form of pins which are arranged on the component and are routed vertically through the boards. These vertically configured pins are particularly suitable for routing through the opening in the glass sheet.

In some embodiments, there is a laser diode which is used to couple polarized laser light into the waveguide. As a rule, this laser diode can likewise be arranged very close to the subassembly itself or even be part of the subassembly, though it is also possible for a plurality of subassemblies and therefore waveguides in various glass sheets to be supplied by a laser diode. For example, a laser diode can be provided for a large power electronics module, the laser light being distributed via feeder waveguides (external to the subassemblies) into the individual subassemblies and the glass sheets arranged therein.

In some embodiments, there are a polarizer and a photodiode, these being used to measure the intensity of laser light that is coupled out of the waveguide. As mentioned above, the laser light that is introduced into the waveguide by the laser diode is changed in its polarization by the magnetic field which is induced by the current-carrying contacting means. By means of the photodiode, the degree of change in the polarization of the incoupled laser light can be measured and the current flow can be inferred thus. As a rule, a photodiode is particularly suitable for this purpose.

In some embodiments, the glass sheet and the waveguide extending therein are embodied in such a way that the waveguide within the glass sheet covers as great a distance as possible, in order to effect a maximally accurate measurement of the Faraday effect which is induced by the current. In this case, it is appropriate for the waveguide within the glass sheet to be routed at least once around the opening. This can also occur more than once in order to further increase the distance. Vertical redirection into a plurality of layers of the glass sheet is also appropriate for the purpose of increasing the distance of the waveguide within the glass sheet. In this case, there are technical processes suitable for structuring a waveguide even in deeper layers of the glass sheet.

In some embodiments, there is an external waveguide leading from the connection points. This serves to connect the waveguide of the glass sheet with the laser diode and/or photodetector which is possibly more remote.

In some embodiments, the external waveguide partially extends within a pin which is provided for this purpose. This means that the external waveguide can be readily routed from the glass sheet onward into a board. To this end, in some embodiments, the external waveguide in the form of a glass body is integrated into the pin. In some embodiments, the pin extends through the board through which, in which, or on which the waveguide extends.

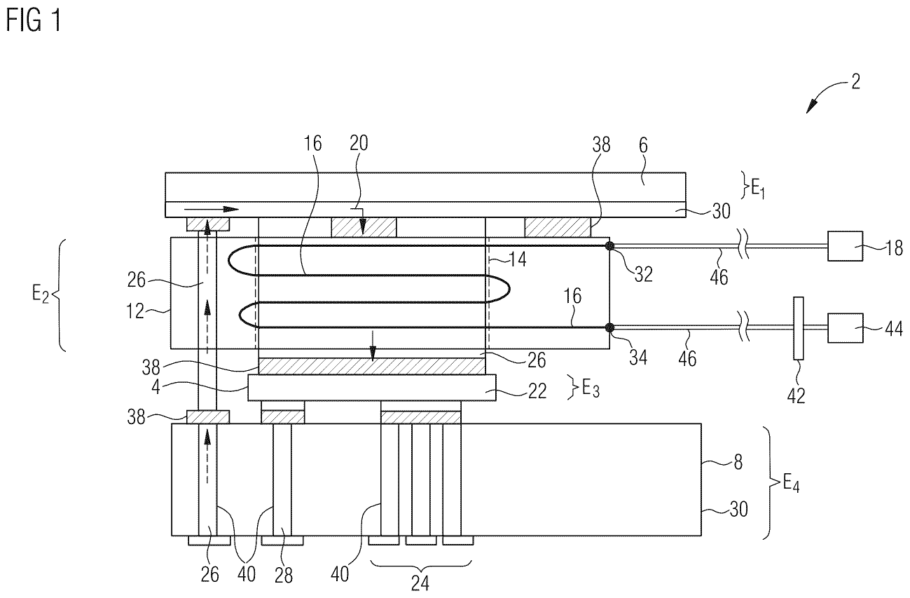

FIG. 1 schematically shows a cross section through a subassembly 2 for a power electronics module incorporating teachings of the present disclosure. The standard construction of such a subassembly in this case comprises a component 4, which is usually attached to a ceramic mounting plate 6 by means of an intermediate metallization layer 36 and soldered connections 38 that also serve as contacting means. Provision is further made for a board 8 which, in this example according to FIG. 1, is embodied in the form of an interposer, an interposer being a rewiring board. The contacting of the component 4 into the board 8 is realized by pins 40 which are poked through the board 8 and soldered or otherwise attached thereto. The component 4 in the present case is a transistor 22 which is configured as a power electronics part, for example for a rectifier.

The transistor 22 as a part 4 in FIG. 1 usually has at least three contacting means in this case. With regard to a field effect transistor, these are referred to as a source contacting means 24, a drain contacting means 26 and a gate contacting means 28. In the case of a bipolar transistor, the terminals would be known correspondingly as emitter, collector and base. Concerning the field effect transistor, for example a MOSFET as is intended to be considered here, the gate contacting means 28 is used to apply a control voltage, by means of which the transistor 22 is continuously switched between the contacting means drain 26 and source 24, so that an electric current flows between the two contacting means source 24 and drain 26. In the case of a power transistor, the higher voltage is on the side of the drain contacting means 26, where potentials between 750 V and 1500 V are usually present. By contrast, a lower voltage of between 600 V and 700 V is normally present at the source contacting means 24.

In the presently chosen construction according to FIG. 1, it can be seen that the drain contacting means 26 is so configured as to be routed from the board 8 via the pins 40 towards the ceramic mounting plate 6, where it is routed via the metallization layer 36 (normally copper) to a so-called top side of the transistor 22. In the embodiment according to FIG. 1, which is also commonly used in power electronics, the transistor 22 is contacted from a top side and a bottom side. The source contacting means 24 is likewise realized via pins 40 to the bottom side of the transistor 22, as shown in FIG. 1. The gate contacting means 28 is also realized from the bottom side of the transistor 22.

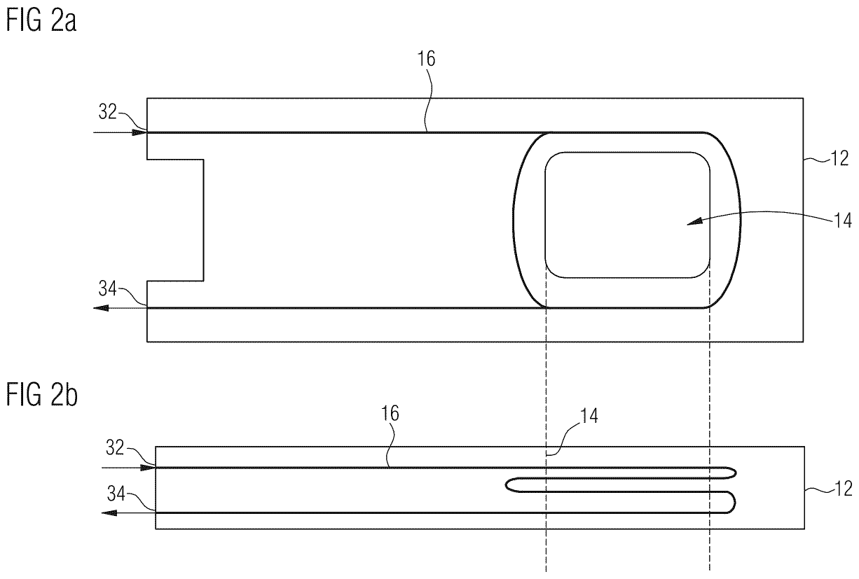

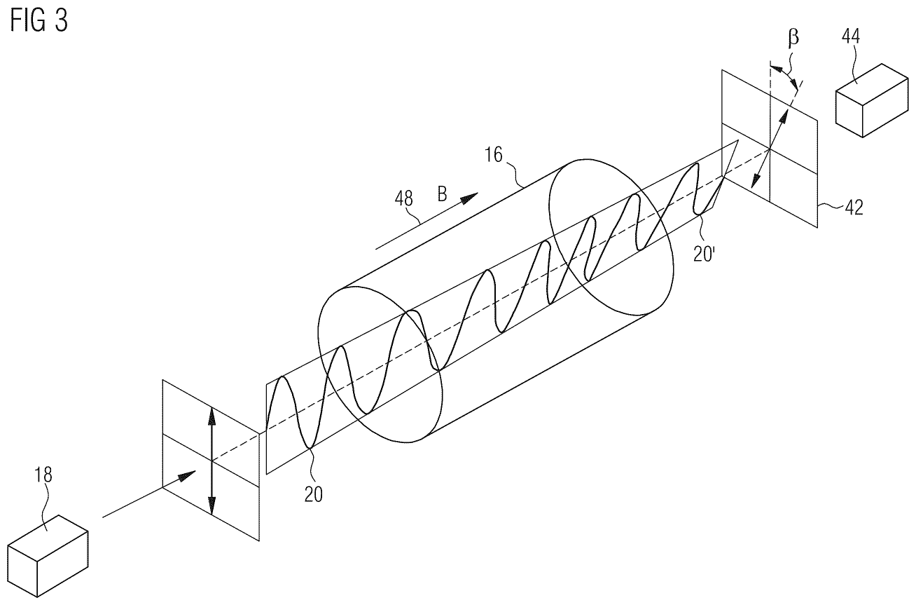

In this respect, the preceding paragraph describes a standard subassembly 2 for a power module. The illustration in FIG. 1 differs from a conventional subassembly according to the prior art in that a glass sheet 12 having the same horizontal extent as the interposer 8 and the ceramic mounting plate 6 of the part 4 is horizontally incorporated in a further layer E2 here. In the embodiment according to FIG. 1, this glass sheet 12 is arranged between the mounting plate 6 and the component 4. The illustration according to FIG. 1 is a distorted illustration which is not to scale. The glass sheet 12 usually has a thickness of 200 μm and is therefore thinner than a conventional board and also thinner than the supporting element 6 or the part 4. The glass sheet 12 can however be between 200 μm and 800 μm thick. The particularity of the glass sheet 12 is that it has an opening 14 through which at least part of the drain contacting means 26 is vertically routed. The further particularity of the glass sheet 12 is that a waveguide 16 serving as an optical waveguide is structured therein. This waveguide 16 in turn has two connection points, one optical connection point 32 for coupling in the laser light 20 (cf. FIGS. 2a, 2b and 3) and a further optical connection point 34 for coupling out the laser light 20. Two further parts are provided in addition to this, the first being a laser diode 18 which is suitable for coupling monochrome and polarized laser light 20 (cf. FIG. 3) into the waveguide 16 via the connection point 32. In this case, said laser light 20 passes through the waveguide 16 until it is coupled out at the connection point 34 and, by virtue of a polarizer 42 which is likewise provided, is detected by a photodetector 44 in the form of a photodiode. Waveguides 46 external to the subassemblies can be provided for the purpose of coupling laser diode 18 and photodetector 44.

FIG. 2a shows a plan view of the glass sheet 12, in which the course of the waveguide 16 is schematically illustrated. In this case, the waveguide 16 is incorporated into the glass sheet 12 in such a way that it extends from the connection point 32 around the opening 14 once and leaves the glass sheet 12 at the connection point 34 for outcoupling laser light. It can moreover be seen in FIG. 2b, which shows a cross section of the illustration according to FIG. 2a, that the waveguide 16 also extends over a plurality of layers in the glass sheet 12 and travels in this way in a meandering manner until it arrives at the connection point 34 for outcoupling the laser light. It is appropriate in this case that the waveguide 16 covers as long a distance as possible through the glass sheet 12, so that the optical effects described below appear as strongly as possible.

It should be noted in this case that optical waveguides 16 can be incorporated into thin glass sheets, with the glass sheet 12, by means of various technical methods disclosed in the prior art. It is firstly possible by means of wet chemical methods to selectively change the optical properties of the glass sheet locally in such a way that the properties of a waveguide 16 occur. Secondly, it is also possible using laser methods to change the material properties even deep within the glass sheet 12 in such a way that they effectively become a waveguide 16.

FIG. 3 illustrates the optical effect on which is based the glass sheet 12 described above, including the laser diode and the photodetector 44. This is the so-called optical Faraday effect, monochrome and polarized laser light being introduced into the waveguide 16 by means of the laser diode 18 in these examples. If a magnetic field 48 is applied on the outside of the waveguide 16, the polarization plane of the laser light 20 is rotated about the angle β according to FIG. 3, so that the laser light 20′ emerging from the waveguide 16 then has a different polarization than the laser light 20 which is coupled into the waveguide 16. The laser light 20′ is guided through a polarizer 42 and detected by means of the photodetector 44 with regard to its intensity. On the basis of the intensity loss between the input laser light 20 and the output laser light 20′, this being induced in particular by the polarizer 42, it is possible to infer the strength of the applied magnetic field 48. These dependencies can be determined empirically and mathematically. From the magnetic field 48 it is then possible to infer the current which flows through the contacting means 24, 26 and/or 28. For a current-carrying conductor, according to Maxwellian laws, also induces a magnetic field and this magnetic field, the magnetic field 48 here, acts on the waveguide 16 and on the laser light 20 which is routed therein.

There consequently exists a causal relationship between the current which flows through the contacting means 24, 26 and/or 28 and the measured intensity that is determined by means of the detector 44. This means that it is possible by means of the detector 44 to infer the strength of the current which flows through the component 4, for example the transistor 22, at corresponding contacting means 24, 26 and/or 28. In the case of FIG. 1, the drain contacting means 26 and therefore the drain current between the ceramic mounting plate 6 and the component 4 is ascertained.

It should be noted in this case that both the laser diode 18 and the detector 44 can in principle be attached to or integrated in the subassembly, though it is probably more appropriate in most cases to transport the laser light 20 to the connection points 32 and 34 of the glass sheet 12 via waveguides 46 external to the subassemblies, so that these components 18, 44 can be arranged decentrally from the subassembly 4, thereby saving structural space.

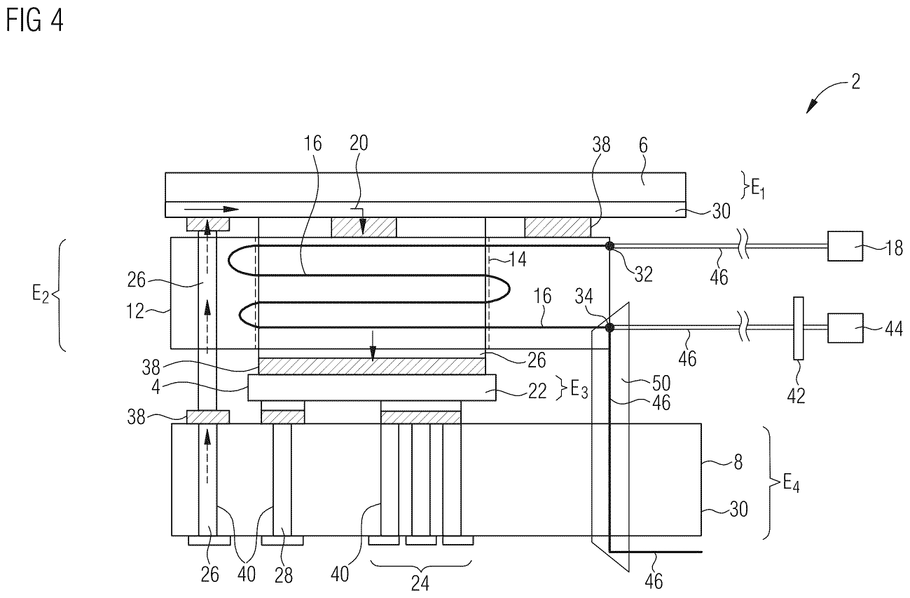

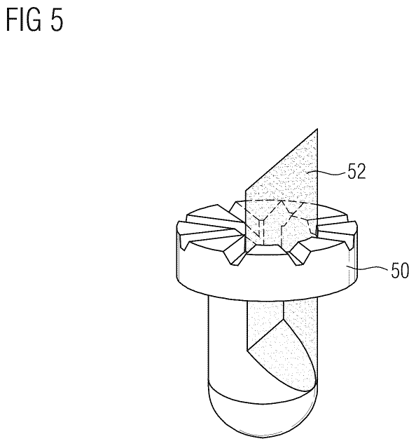

An alternative routing of the external waveguide 46 is illustrated in FIGS. 4 and 5, the external waveguide being routed in an optical pin 50 which is intended specifically for this purpose, starting from the glass sheet 12 and the optical connection points thereof 32 and 34. Within this optical pin 50, the external waveguide 46 can then extend in a glass body 52 which is integrated in the pin 50 as illustrated in FIG. 5 by way of example. This construction has the advantage inter alia that the external waveguide can be routed vertically in the subassembly, in particular in a mechanically reliable manner, and after horizontal (for example prismatic) redirection extends further within or on one of the possible boards 8 and is thus routed to the laser diode 18 and/or the photodetector 44.

The pin or pins 50 are designed in such a way that they can be produced using conventional manufacturing methods such as flow or reflow soldering, sintering and/or interference fitting. This means that no special processes are required for this purpose. Furthermore, the optical areas (such as for example the connection points 32, 34) can be sealed externally by means of suitable construction and interconnection technology and thus protected against contamination.

Potential advantages may be produced in the form of:
Simpler technical coupling of the waveguides 16, 46 and the signals carried thereby between different circuit support layers.
A coupling is provided with complete conductive separation, resulting in total electrical isolation.
The use of conventional construction technologies (for example common soldering and sintering processes) is therefore possible without additional expense.
Protection against external contamination is guaranteed.

### LIST OF REFERENCE SIGNS

2 Subassembly
4 Component
6 Mounting plate
8 Board
E Layers
10 Contacting means
12 Glass sheet
14 Opening
16 Waveguide
18 Laser diode
20 Laser light
22 Transistor
24 Source contacting means
26 Drain contacting means
28 Gate contacting means
30 Interposer≙rewiring board
32 Optical connection point—incoupling
34 Optical connection point—outcoupling
36 Metallization layer
38 Soldered connection
40 Pin
42 Polarizer
44 Photodetector
46 External waveguide
48 Magnetic field
50 PIN external waveguide
52 Glass body

1. An electronic subassembly comprising:
an electronic component;
a board;
wherein the component and the board extend horizontally relative to each other in various layers within the subassembly;
contacting means of the electronic component extending vertically in the subassembly;
a glass sheet incorporated into the subassembly in a horizontal installation position;
a horizontal opening in the glass sheet through which is routed at least part of the contacting means;
an optical waveguide structured in the glass sheet; and
two optical connection points for the waveguide by which polarized laser light can be coupled into and out of the waveguide;
wherein the glass sheet is arranged between a mounting plate and the component.

2. The subassembly as claimed in claim 1, wherein:
the component comprises a power electronics component; and
the subassembly comprises a power electronics subassembly.

3. The subassembly as claimed in claim 1, wherein the component comprises a transistor or a diode.

4. The subassembly as claimed in claim 3, wherein the component has at least two current-carrying contacting means.

5. The subassembly as claimed in claim 4, wherein at least one of the at least two current-carrying contacting means extends through the opening of the glass sheet.

6. The subassembly as claimed in claim 1, wherein the contacting means comprise pins routed vertically through the board.

7. The subassembly as claimed in claim 1, further comprising a laser diode to couple polarized laser light into the waveguide.

8. The subassembly as claimed in claim 7, further comprising a polarizer and a photodiode to measure an intensity of laser light coupled out of the waveguide.

9. The subassembly as claimed in claim 1, wherein the waveguide extends within the glass sheet at least once around the opening.

10. The subassembly as claimed in claim 1, wherein the waveguide is vertically redirected within the glass sheet and extends in a plurality of layers of the glass sheet.

11. The subassembly as claimed in claim 1, further comprising an external waveguide leading from the connection points.

12. The subassembly as claimed in claim 11, wherein the external waveguide partially extends within a pin.

13. The subassembly as claimed in claim 12, wherein the external waveguide comprises a glass body integrated into the pin.

14. The subassembly as claimed in claim 11, wherein the external waveguide extends at least partially in or on the board.

15. The subassembly as claimed in claim 14, wherein the pin extends through the board.
